(19) United States
(12) Patent Application Publication
(10) Pub. No.: US 2026/0305242 A1
(43) Pub. Date: Oct. 1, 2026

(54) RACK APPARATUS AND METHOD FOR OPERATING WAFER CARRIER HANDLING SYSTEM

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Yang SUN, Shanghai City (CN); Lan ZHANG, Shanghai City (CN); Chun LIN, Shanghai City (TW); Yalan ZHANG, Shanghai City (CN); Guo CHEN, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/178,463

(22) Filed: Apr. 14, 2025

(30) Foreign Application Priority Data
Mar. 26, 2025 (CN) 202520551655.1

(51) Int. Cl. H10P 72/30; B25J 11/00; B65G 1/04

(52) U.S. Cl. CPC H10P 72/3404; B25J 11/0095; B65G 1/04; B65G 2201/0297

(57) ABSTRACT

A method for operating a wafer carrier handling system is provided. The method includes causing a robot arm of a transfer robot to approach a rack apparatus along an approaching path, wherein the robot arm grips a wafer carrier; automatedly opening a door of the rack apparatus when the robot arm of the transfer robot is in front of the rack apparatus; when the door of the rack apparatus is open, using the robot arm, placing the wafer carrier onto the rack apparatus; causing the robot arm to leave the rack apparatus; and after causing the robot arm to leave the rack apparatus, automatedly closing the door of the rack apparatus.

### PRIORITY CLAIM AND CROSS-REFERENCE

The present application claims priority to China Application Serial Number 202520551655.1, filed Mar. 26, 2025, which is herein incorporated by reference.

### BACKGROUND

Multiple wafers are stored and transported together in batches by a wafer carrier throughout a semiconductor fabrication facility (“fab”) between the loadports of different wafer processing tools or equipment. Such tools generally perform various photolithography, etching, material/film deposition, curing, annealing, inspection, or other processes used in IC chip manufacturing.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a rack apparatus in accordance with some embodiments of the present disclosure.

FIG. 1B is a top view illustrating a wafer carrier handling system including the rack apparatus of FIG. 1A in accordance with some embodiments of the present disclosure.

FIG. 2 is schematic view of an automated door system of the rack apparatus of FIG. 1A.

FIGS. 3A and 3B are a schematic view of a lower guide rail assembly of the automated door system of FIG. 2.

FIG. 4 is a schematic view of a middle guide rail assembly of the automated door system of FIG. 2.

FIG. 5 is a schematic view of an upper guide rail assembly of the automated door system of FIG. 2.

FIG. 6 is schematic view of an automated door system of the rack apparatus of FIG. 1A.

FIG. 7 is a schematic view of a floor portion of the rack apparatus of FIG. 1A.

FIG. 8A is schematic view of a floor of the rack of FIG. 1A.

FIG. 8B is schematic view of the floor of FIG. 8A with a wafer carrier placed thereon.

FIG. 9 is a schematic view of a lower portion of the rack apparatus of FIG. 1A.

FIG. 10 is a flow chart of a method for operating a wafer carrier handling system according to some embodiments of the present disclosure.

FIGS. 11-14 are top views of a rack apparatus and a transfer robot at various operating stages during transferring a wafer carrier into a rack apparatus according to some embodiments of the present disclosure.

FIGS. 15-18 are top views of a rack apparatus and a transfer robot at various operating stages during transferring a wafer carrier away a rack apparatus according to some embodiments of the present disclosure.

FIG. 19 shows pulses versus time for various steps when operating the rack apparatus according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

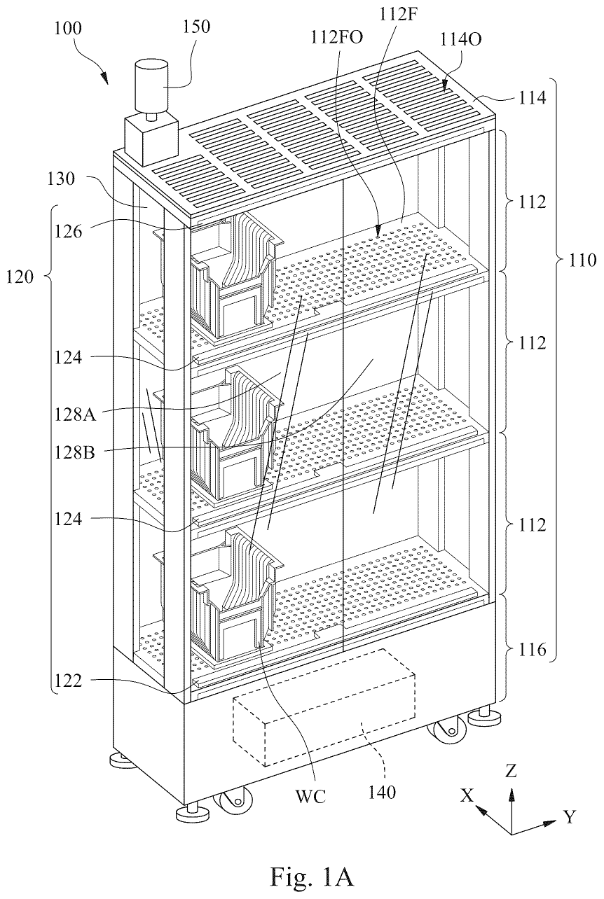

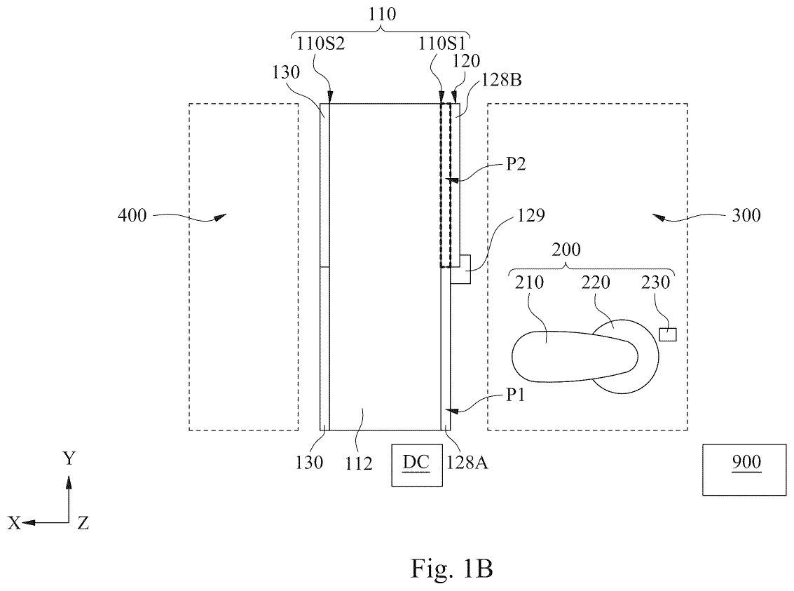

FIG. 1A is a schematic view of a rack apparatus 100 in accordance with some embodiments of the present disclosure. The rack apparatus 100 includes a rack 110, an automated door system 120, doors 130, an gas exhaust system 140, and an alarm device 150. The rack 110 may include plural rack layers 112 one stacking over another, a ceiling 114 over the rack layers 112, and a cabinet 116 below the rack layers 112. The rack layers 112, the ceiling 114, and the cabinet 116 are stacked along a direction Z. Each of the rack layers 112 may have a floor 112F where the wafer carrier WC is put. In the context, three rack layers 112 are illustrated. In some alternative embodiments, the number of the rack layers 112 may be in a range from 1 to 10. The different rack layers 112 may accommodate the wafer carrier WC at different steps of the process. In some embodiments, the floor 112F of each of the rack layers 112, where the wafer carrier WC is put, may have plural floor openings 112FO allowing the fluid communication among the rack layers 112. The gas exhaust system 140 is located in the cabinet 116. And, a floor 112F of the bottommost one of the rack layers 112 may have plural floor openings 112FO allowing the fluid communication between the gas exhaust system 140 and the bottommost one of the rack layers 112. The ceiling 114 may have plural ceiling openings 114O to allow fluid communication between the topmost one of the rack layers 112 and the environment. Through the configuration, one or more wafer carriers WC can be disposed in the rack layers 112 for purging the gas outgassing from wafers, for example, by the gas exhaust system 140. The wafer carrier WC may include a wafer cassette, a front-opening unified pod (FOUP), a pod, a container, or a similar type of device configured to hold and/or store plural wafers.

FIG. 1B is a top view illustrating a wafer carrier handling system including the rack apparatus 100 of FIG. 1A in accordance with some embodiments of the present disclosure. Reference is made to FIGS. 1A and 1B. The rack 110 has opposite first and second sides 110S1 and 110S2, in which the automated door system 120 is located at a first side 110S1 of the rack 110, and the doors 130 are located at a second side 110S2 of the rack 110.

In some embodiments, the automated door system 120 can be opened or closed automatedly, and a transfer robot 200 may move a wafer carrier into or out of one or the rack layers 112 of the rack 110. The transfer robot 200 may be located in the empty robot area 300 at the first side 110S1 of the rack 110. In some embodiments, the transfer robot 200 may be moved in the robot area 300. The transfer robot 200 may have a robot arm 210 and a stationary base 220 supporting the robot arm 210. For example, the robot arm 210 is capable of extending into the rack layers 112 along the direction X. In some embodiments, the robot arm 210 is equipped with multiple degrees of freedom (joints) to allow for flexible movement and positioning. In some examples, the robot arm 210 may extend along the directions X, Y, and Z for transferring the wafer carrier WC. In the context, the directions X, Y, and Z are orthogonal to each other. The robot arm 210 may include an end effector (gripper) to securely hold the wafer carrier, using vacuum suction or mechanical clamps.

In some embodiments, the doors 130 can be opened or closed manually for manually moving the wafer carrier WC into the rack layer 112 or out of the rack layer 112. For example, an operator can walk into the empty area 400 at the second side 110S2 of the rack 110. The operator can open the door 130, move a wafer carrier WC into the rack layer 112 or out of the rack layer 112, and then close the door. In some embodiments, the doors 130 may have transparent windows such that the operator can observe the wafer carrier WC through the transparent windows without opening the doors 130. The alarm device 150 may send an alarm signals to alert operators when abnormal conditions (e.g., the robot arm 210 hits the doors 128A and 128B) occurs.

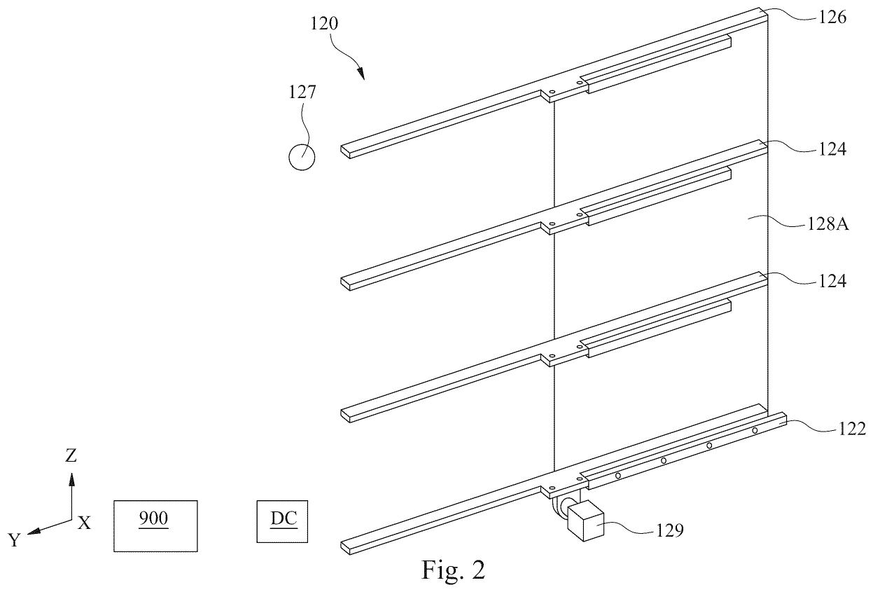

FIG. 2 is a schematic view of an automated door system 120 of the rack apparatus 100 of FIG. 1A. Reference is made to FIG. 1A and FIG. 2. The automated door system 120 includes a lower guide rail assembly 122, middle rail assemblies 124, an upper guide rail assembly 126, two doors 128A and 128B, a driving unit 129, and a door controller DC. The guide rail assembly 122, 124, and 126 provides a stable track for the doors 128A and 128B to slide along the direction Y, which is substantially orthogonal to the direction X. The lower guide rail assembly 122 is securely mounted on the bottommost floor 122F and helps align the doors 128A and 128B as they open and close. The middle rail assemblies 124 may be mounted on the floors 122F, and the middle rail assemblies 124 is configured to support the doors 128A and 128B and keep the doors 128A and 128B aligned vertically. The middle rail assemblies 124 help distribute the weight of the doors 128A and 128B, enhancing stability and durability. The upper guide rail assembly 126 is mounted above the doors 128A and 128B, for example, on the ceiling 114, and provides additional support and guidance. In some embodiments, the doors 128A and 128B may be transparent doors (e.g., transparent glass or poly (methyl methacrylate) (PMMA)), such that the operator can observe the wafer carrier WC through the transparent doors 128A and 128B.

The driving unit 129 is the mechanism that powers the movement of the door 128A/128B. The driving unit 129 can be an electric motor that controls the opening and closing of the doors 128A and 128B. The driving unit 129 may include features such as speed control, safety sensors to prevent obstruction, and integration with access control systems. In the present embodiments, the driving unit 129 is housed by the lower guide rail assembly 122. In some alternative embodiments, the driving unit 129 is housed by the upper guide rail assembly 126. The driving unit 129 may be communicated connected with the door controller DC, and the driving unit 129 can open doors 128A and 128B automatedly in response to motion sensor, manual triggers, or other triggering signals through the door controller DC.

In some embodiments, a controller 230 of the transfer robot 200 may send the triggering signals of the door controller DC, thereby opening or closed the doors 128A and 128B in response of the movement of the robot arm 210. The door controller DC of the automated door system 120 may be communicated connected with the controller 230 of the transfer robot 200. When the robot arm 210 (referring to FIG. 1B) moves toward the rack 110, the controller 230 of the transfer robot 200 may send a signal to the driving unit 129 to activate when the robot arm 210 is at a determined position in front of the rack 110. The doors 128A and 128B may slide open smoothly along the guide rail assemblies 122, 124, and 126, providing convenient access to the rack 110. When the transfer robot 200 (referring to FIG. 1B) is controlled to move the robot arm 210 away from the rack 110, for example, when the robot arm 210 being at a determined position in front of the rack 110, the controller 230 of the transfer robot 200 may send a signal to the driving unit 129 to close the door 128A/128B automatedly.

In some embodiments, the automated door system 120 may include a motion sensor 127 communicated connected with the door controller DC. The motion sensor 127 may be mounted one or more of the lower guide rail assembly 122, the middle rail assemblies 124, the upper guide rail assembly 126. When the robot arm 210 (referring to FIG. 1B) approaches the automated door system 120, the motion sensor 127 may detect their presence, signaling the driving unit 129 to activate. The door 128A/128B may slide open smoothly along the guide rail assemblies 122, 124, and 126, providing convenient access to the rack 110. Once the robot arm 210 leaves the automated door system 120, the motion sensor 127 triggers the door 128A/128B to close automatedly. For example, the motion sensor 127 may be infrared sensors, microwave sensors, laser sensors, pressure sensors, the like, or the combination thereof.

In some embodiments, the door controller DC of the automated door system 120 may be communicated connected with a central control system 900. The central control system 900 may be communicated connected with the transfer robot 200 (referring to FIG. 1B) (e.g., a controller 230 of the transfer robot 200). When the central control system 900 control the transfer robot 200 (referring to FIG. 1B) to move the robot arm 210 toward the rack 110, the central control system 900 may send a signal to the driving unit 129 to activate when the robot arm 210 is at a determined position in front of the rack 110. The door 128A/128B may slide open smoothly along the guide rail assemblies 122, 124, and 126, providing convenient access to the rack 110. When the central control system 900 control the transfer robot 200 (referring to FIG. 1B) to move the robot arm 210 away from the rack 110. For example, when the transfer robot 200 being at a determined position in front of the rack 110, the central control system 900 may send a signal to the driving unit 129 to close the door 128A/128B automatedly.

The door controller DC may include processors, such as microprocessors, distributed processing systems, application specific integrated circuits (ASIC), or the like. In some embodiments, the door controller DC may receive signals of the motion sensor 127 and/or the central control system 900 and control the operations of the driving unit 129 based on the signal. The door controller DC may control the operations of the driving unit 129 based on the signal by using the processor reading out and executing the program stored in the storage medium. The program may be one that has been stored in the computer-readable storage medium, or may be one that has been installed to the storage medium of the door controller DC.

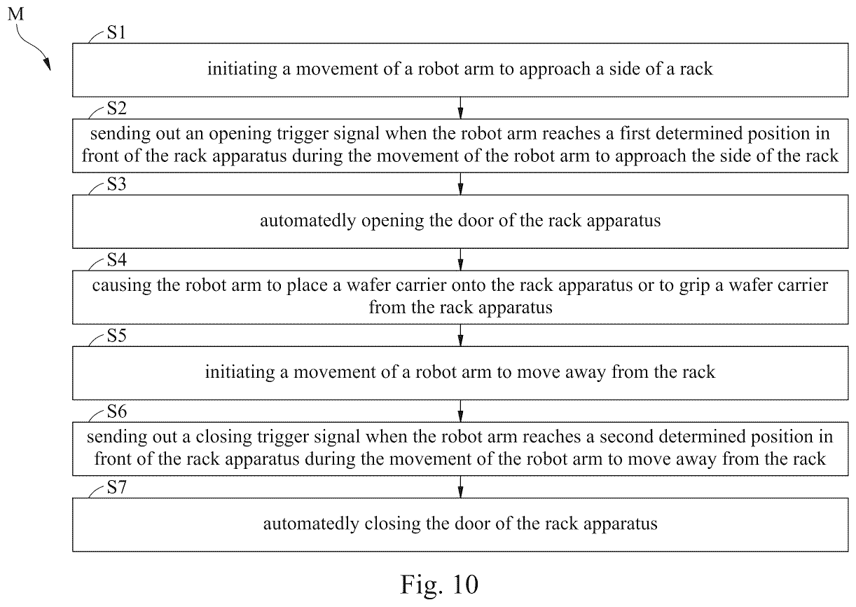

The central control system 900 may include a computer-readable storage medium and a processor coupled to the computer-readable storage medium. The processor is configured to execute programming instructions stored in the computer-readable storage medium. In some embodiments, the computer-readable storage medium stores programming instructions that performs various steps of the methods in FIG. 10 discussed later. The central control system 900 controls the operations of the driving unit 129 and the transfer robot 200 by using the processor reading out and executing the program stored in the storage medium. The program may be one that has been stored in the computer-readable storage medium, or may be one that has been installed to the storage medium of the central control system 900. In some embodiments, the central control system 900 may include processors, central processing units (CPU), multi-processors, distributed processing systems, application specific integrated circuits (ASIC), or the like.

In some embodiments, the central control system 900 may include an input device, and an output device, or a combined input/output device for enabling user interaction. The output device is configured to provide information to operators. For example, the output device. The input device comprises, for example, a keyboard, keypad, mouse, trackball, trackpad, and/or cursor direction keys for communicating information and commands to the processor of the central control system 900. The output device comprises, for example, a display, a printer, a voice synthesizer, etc. for communicating information to a user.

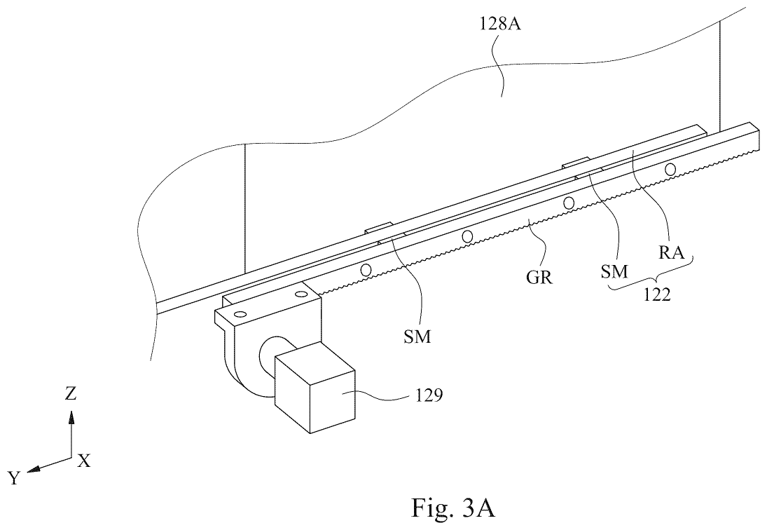

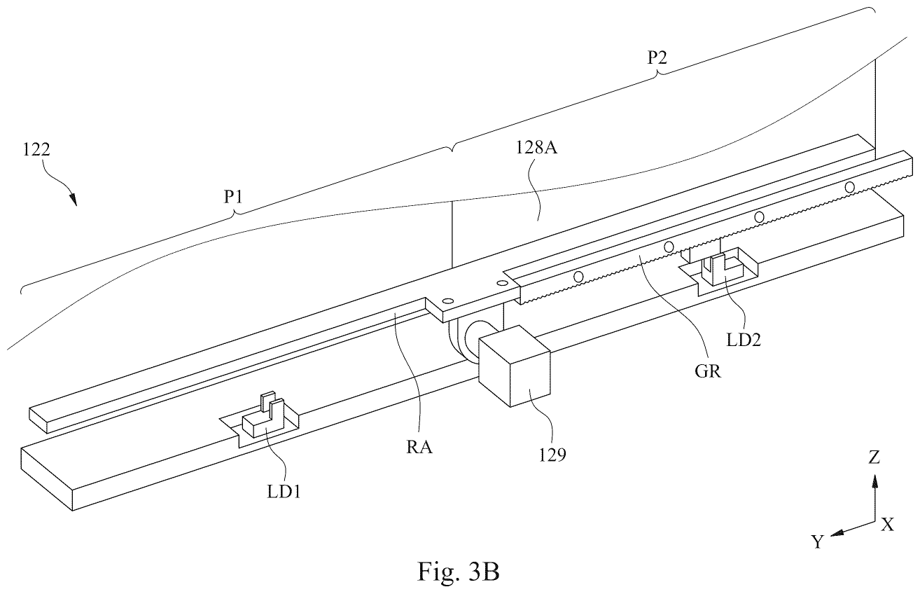

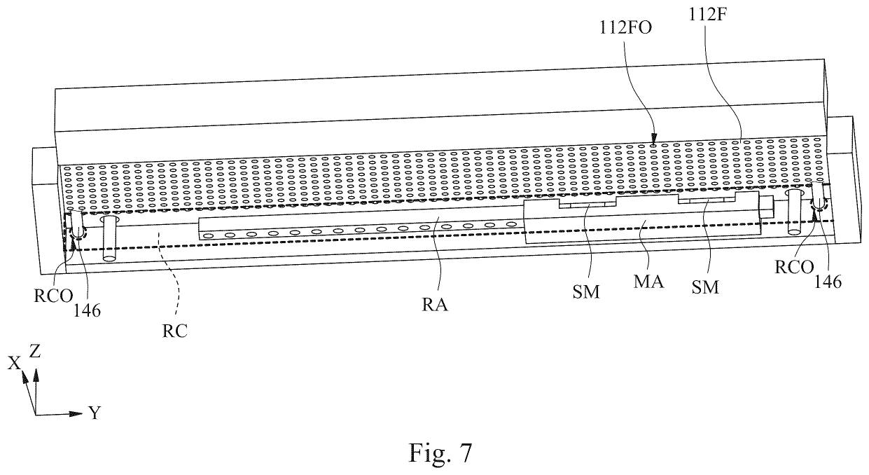

FIGS. 3A and 3B are a schematic view of a lower guide rail assembly 122 of the automated door system 120 of FIG. 2. The lower guide rail assembly 122 includes a rail RA and slide members SM capable of moving/sliding over the rail RA along the direction Y. The rails RA may provide support and guide movement. The rail RA is made of rigid materials like steel or aluminum to withstand loads (e.g., the door 128A). The slide members SM may be fixed/connected with suitable mounting mechanisms (e.g., the mounting mechanisms MA in FIG. 7) for attaching loads or components (e.g., the door 128A).

In some embodiments, the slide members SM may be coupled with the driving unit 129 by a gear rack GR. The driving unit 129 can be an electric motor that divides a full rotation into a series of discrete steps. It is known for its precision and ability to control position accurately without the need for feedback systems. The driving unit 129 can be a stepper motor in some embodiments. In some embodiments, the gear rack GR is a flat and linear component with teeth cut along one side. It converts rotational motion from the electric motor into linear motion when engaged with a gear or pinion. When a gear turns, its teeth mesh with those of the gear rack GR, causing the gear rack GR to move linearly along its length. Through the gear rack GR, the slide members SM holding the door 128A can be moved/drived by the driving unit 129. The slide members SM can be fixed to the gear rack GR through suitable fixing members, such as screws.

In some embodiments of the present disclosure, the automated door system 120 may further include light sensors LD1 and LD2 configured to detect the positions of the door 128A. For example, the light sensor LD1 is configured to check whether the doors 128A is at the first region P1 (door closed), and the light sensor LD2 is configured to check whether the doors 128A is at the second region P2 (door open). The light sensors LD1 and LD2 may be below the lower guide rail assembly 122 and offset from the rail RA of the lower guide rail assembly 122. The first region P1 and the second region P2 are aligned with each other in the top view.

In some embodiments, the light sensors LD1 and LD2 may include a light detector that can sense and measure light intensity or the presence of light. For example, when the doors 128A is at the first region P1, and the second region P2 is absent from the doors 128A, the light sensor LD1 would be shielded by one or more of the gear rack GR, the slide members SM, and the doors 128A and may not detect ambient light. At the same time, the light sensor LD2 would be uncovered by the gear rack GR, the slide members SM, and the doors 128A and may detect ambient light. On the other hand, when the door 128A is at the second region P2, and the first region P1 is absent from the door 128A, the light sensor LD2 would be shielded by one or more of the gear rack GR, the slide members SM, and the doors 128A and may not detect ambient light. At the same time, the light sensor LD1 would be uncovered by the gear rack GR, the slide members SM, and the doors 128A and may detect ambient light.

In some embodiments, each of the light sensors LD1 and LD2 may include a light emitter configured to emit light (e.g., along the direction Z) and a light receiver configured to detect the light reflected by one or more of the gear rack GR, the slide members SM, and the doors 128A. Thus, when the doors 128A is at the first region P1, the second region P2 is absent from the doors 128A, the light emitted by the light emitter of the light sensor LD1 would be detected by the light receiver of the light sensor LD1 through the reflection at the one or more of the gear rack GR, the slide members SM, and the doors 128A, and the light emitted by the light emitter of the light sensor LD2 would not be detected by the light receiver of the light sensor LD2. And, when the doors 128A is at the second region P2, the first region P1 is absent from the doors 128A, the light emitted by the light emitter of the light sensor LD2 would be detected by the light receiver of the light sensor LD2 through the reflection at the one or more of the gear rack GR, the slide members SM, and the doors 128A, and the light emitted by the light emitter of the light sensor LD1 would not be detected by the light receiver of the light sensor LD1.

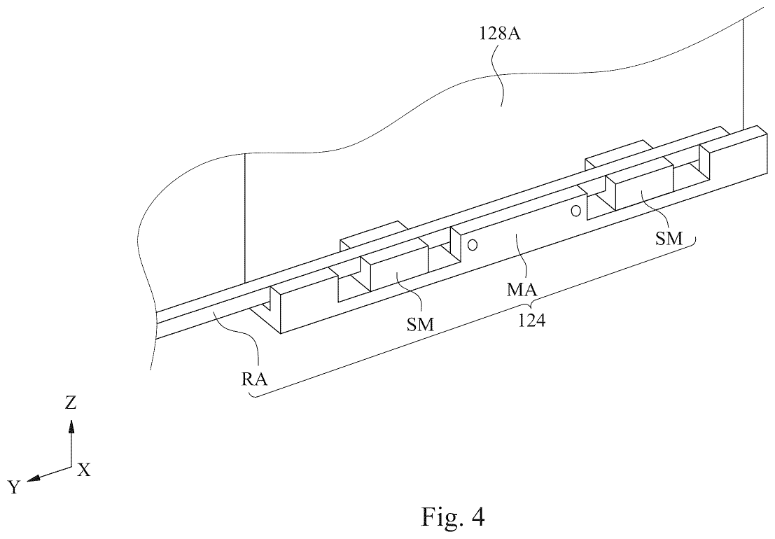

FIG. 4 is a schematic view of a middle guide rail assembly 124 of the automated door system of FIG. 2. The middle guide rail assembly 124 includes a rail RA and slide members SM capable of moving/sliding along the rail RA. The rails RA may provide support and guide movement. The rail RA is made of rigid materials like steel or aluminum to withstand loads (e.g., the door 128A). The slide members SM may be fixed/connected with mounting mechanisms MA for attaching loads or components (e.g., the door 128A). The slide members SM are made of rigid materials like copper coated with chromium. The slide members SM are made of rigid materials like copper coated with chromium made of rigid materials like steel or aluminum to withstand loads (e.g., the door 128A).

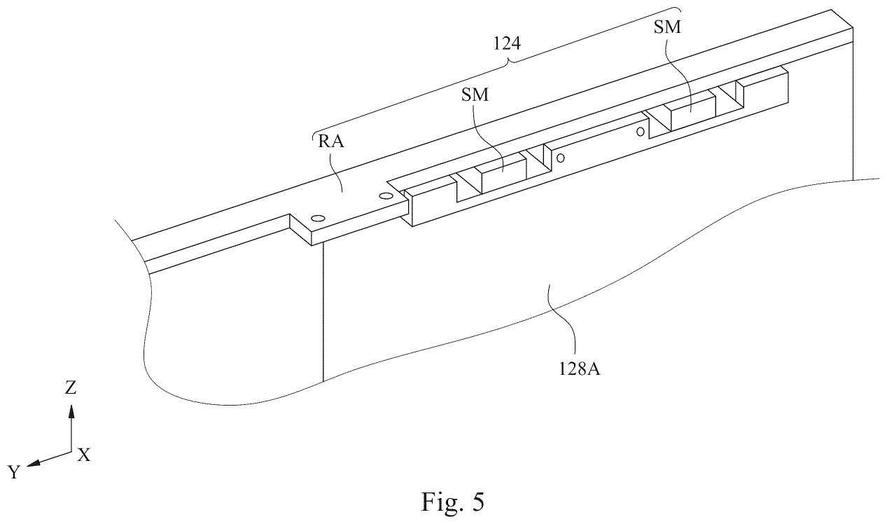

FIG. 5 is a schematic view of an upper guide rail assembly 126 of the automated door system of FIG. 2. The upper guide rail assembly 126 includes a rail RA and slide members SM capable of moving/sliding along the rail RA. The rails RA may provide support and guide movement. The rail RA is made of rigid materials like steel or aluminum to withstand loads (e.g., the door 128A). The slide members SM may be fixed/connected suitable mounting mechanisms for attaching loads or components (e.g., the door 128A). The slide members SM are made of rigid materials like copper coated with chromium.

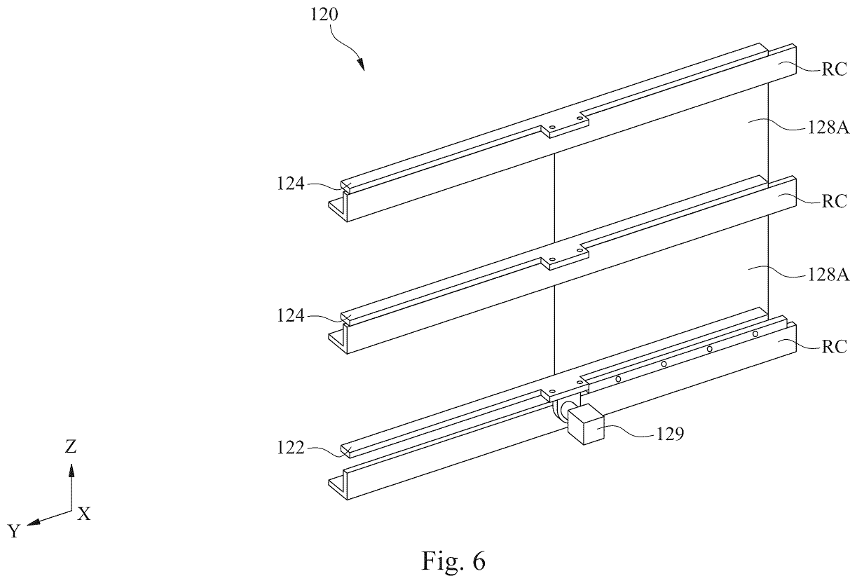

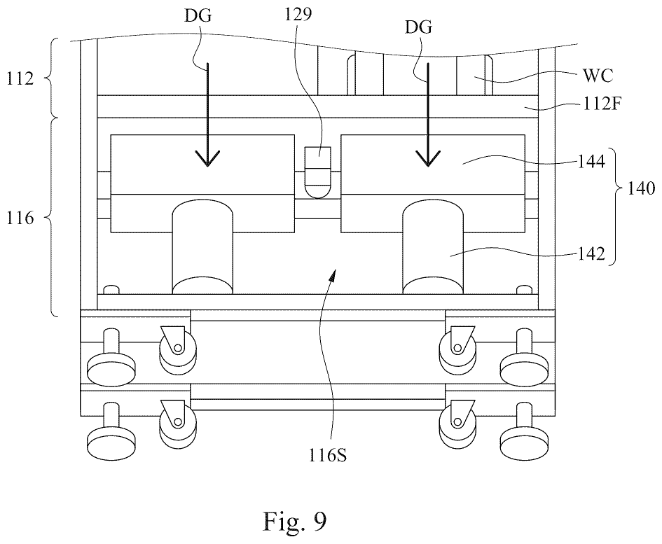

FIG. 6 is schematic view of an automated door system of the rack apparatus 100 of FIG. 1A. FIG. 7 is a schematic view of a floor portion of the rack apparatus of FIG. 1A. In some embodiments, the rack apparatus 100 includes rail covers RC surrounding the lower guide rail assembly 122 and the middle guide rail assembly 124, respectively, thereby preventing the lower guide rail assembly 122 and the middle guide rail assembly 124 from particle dusts. For example, in FIG. 7, a rail cover RC surround the rail RA and the slide members SM. The rail cover RC may run in parallel with the rails RA, for example, along the direction Y. In some embodiments, the rail cover RC may have holes RCO gaseously connected with exhaust pipes 146 of the gas exhaust system 140, which may be connected with a pump, for example, through the exhaust pipes 142 and the exhaust funnels 144 in FIG. 9 later. Through the configuration, a gas is exhausted away from the space surrounded by the rail cover RC through the holes RCO and the exhaust pipes 146 of the gas exhaust system 140, thereby evacuating particles produced by the rail RA and the slide members SM from the rack layers 112.

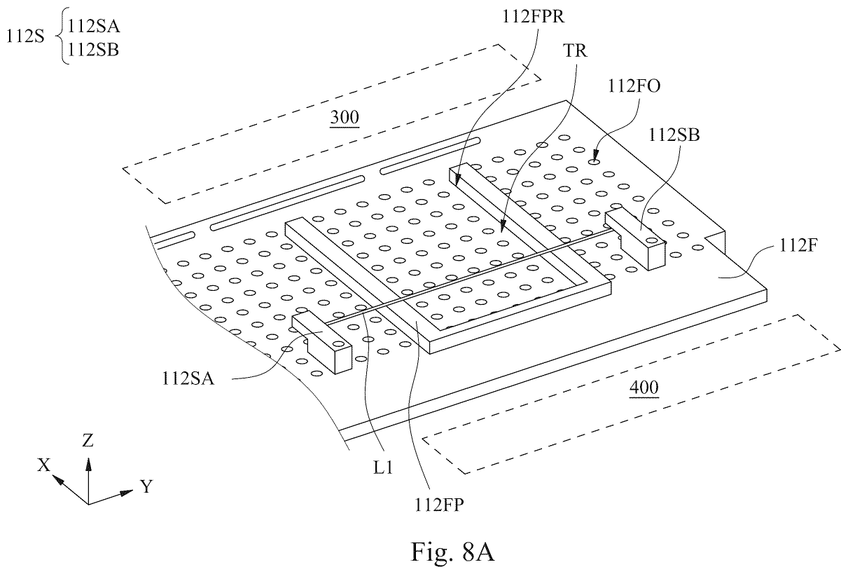

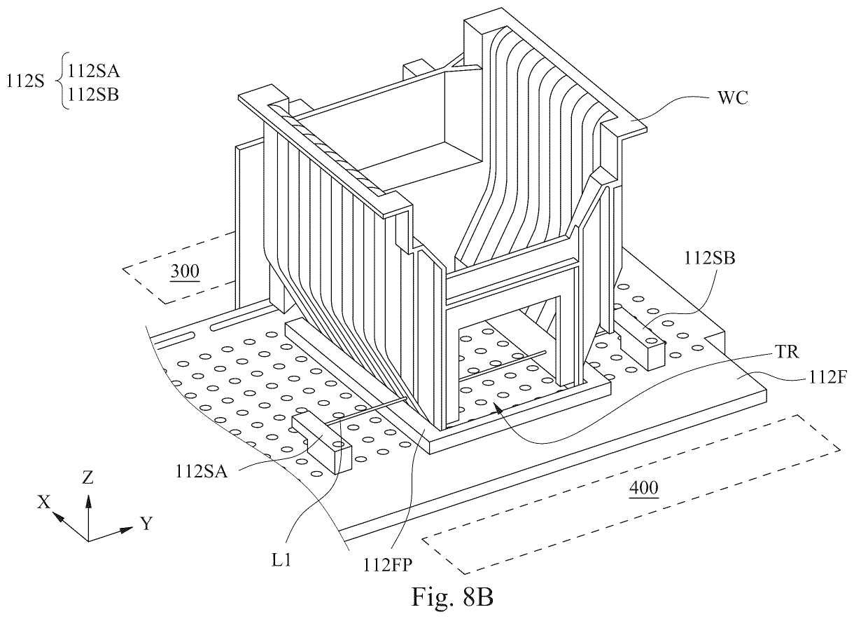

FIG. 8A is schematic view of a floor 112F of the rack 110 of FIG. 1A. FIG. 8B is schematic view of the floor 112F of FIG. 8A with a wafer carrier WC placed thereon. Reference is made to FIGS. 1A, 8A, and 8B. In some embodiments, the floors 112F have positioning elements 112FP configured to limit the wafer carrier WC to a target region TR. For example, the positioning elements 112FP may surround the target region TR but have an opening 112FPR facing the robot area 300. Through the configuration, the transfer robot 200 in the robot area 300 may transfer the wafer carrier WC by gripping and dragging the wafer carrier WC on the floor 112F without lifting the wafer carrier WC above the floor 112F. And, the operator in the area would lift wafer carrier WC above the floor 112F (even above the positioning elements 112FP) for manually transfer the wafer carrier WC.

In some embodiments, the rack layer 112 (referring to FIG. 1A) may have a light sensor 112S disposed over the floor 112F. The light sensor 112S is configured to detect the locations of the wafer carrier WC. In some examples, the light sensor 112S may include a light emitter 112SA configured to emit light L1 along a direction Y and a light receiver 112SB configured to detect the light L1. The light L1 goes through a target region TR surrounded by the positioning elements 112FP. The direction Y is substantially orthogonal to the direction X when viewed from top. Thus, when the wafer carrier WC is located in the target region TR, the light L1 is blocked or weaken by wafer carrier WC, and the detection result of the light receiver 112SB may show a weak light intensity. For example, materials of the wafer carrier WC may absorb or reflect the light L1. When the target region TR is free of the wafer carrier WC, the light L1 emitted from the light emitter 112SA would be fully received by the light receiver 112SB, and the detection result of the light receiver 112SB may show a strong light intensity. Thus, the light receiver 112SB configured to detect the light L1 may send out a signal to indicate whether the wafer carrier WC is placed in the target region TR accurately or not.

FIG. 9 is a schematic view of a lower portion of the rack apparatus of FIG. 1A. Reference is made to FIGS. 1A and 9. The gas exhaust system 140 may include plural exhaust pipes 142 and plural exhaust funnels 144. The exhaust pipes 142 may be connected with a pump. The exhaust funnels 144 are respectively connecting the exhaust pipes 142 to the bottommost one of the rack layers 112. Through the configuration, by operating the gas exhaust system 140, a continuous downward gas flow DG is generated from the environment, through the ceiling 114 (e.g., through the ceiling openings 114O) and the rack layers 112 (e.g., through the floor opening 112O), and to the gas exhaust system 140. The continuous downward gas flow DG is generated without considering the movement of the wafer carrier WC. With the rack 110 and the gas exhaust system 140, it is effectively to remove the fluorine-containing gas outgassing from the wafer, thereby reducing the fluorine-containing gas around the wafer. The configuration of the exhaust funnels 144 enlarge a cross-section area that the gas flow DG passes through. In the illustrated embodiments, the gas exhaust system 140 is connected to a bottom of the rack layer 112. In some alternative embodiments, the gas exhaust system 140 may be connected to other portions of the rack layer 112 for providing better airflow to remove the outgassing.

In the cabinet 116, while the gas exhaust system 140 is gaseously connected with the rack layers 112, the space 116S around the gas exhaust system 140 is gaseously isolated from the rack layers 112.

FIG. 10 is a flow chart of a method M for operating a wafer carrier handling system according to some embodiments of the present disclosure. The method M includes steps S1-S7. At step S1, a movement of a robot arm is initiated to approach a side of a rack. At step S2, an opening trigger signal is sent out when the robot arm reaches a first determined position in front of the rack apparatus during the movement of the robot arm to approach the side of the rack. At step S3, the door of the rack apparatus 100 is automatedly opened. At step S4, the robot arm is caused to place a wafer carrier WC onto the rack apparatus 100 or to grip a wafer carrier WC from the rack apparatus 100. At step S5, a movement of a robot arm is initiated to move away from the rack. At step S6, a closing trigger signal is sent out when the robot arm reaches a second determined position in front of the rack apparatus during the movement of the robot arm to move away from the rack. At step S7, the door of the rack apparatus is automatedly closed. It is understood that additional steps may be provided before, during, and after the steps S1-S7 shown in FIG. 10, and some of the steps described below can be replaced or eliminated for additional embodiments of the method. The order of the operations/processes may be interchangeable.

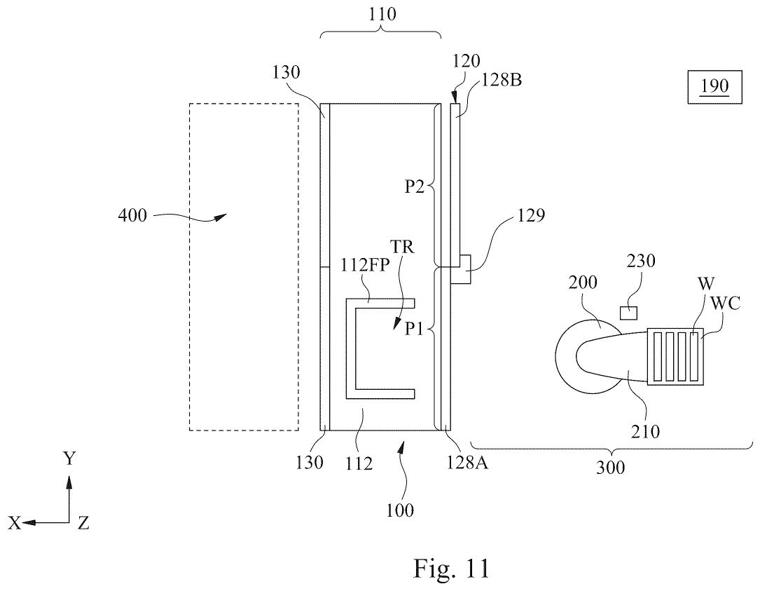

FIGS. 11-14 are top views of a rack apparatus 100 and a transfer robot 200 at various operating stages during transferring a wafer carrier WC into a rack apparatus 100 according to some embodiments of the present disclosure. Reference is made to FIG. 11. The robot arm 210 grips a wafer carrier WC from a semiconductor processing apparatus or other storage rack. For example, the wafer carrier WC may be located on a load port of a semiconductor processing apparatus (e.g., lithography apparatus), and gripped and moved away from the load port of the semiconductor processing apparatus (e.g., lithography apparatus) by the robot arm 210. In such embodiments, plural wafers W are located inside the wafer carrier WC. The wafers W are processed by the semiconductor process (e.g., lithography process) by processing chambers of the semiconductor processing apparatus (e.g., lithography apparatus).

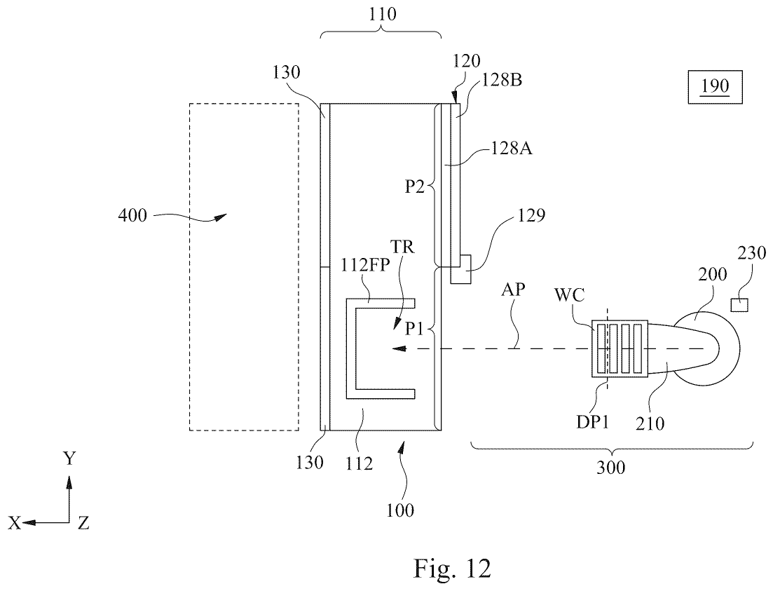

Reference is made to FIG. 10 and FIG. 12. The method M begins at step S1, where a movement of a robot arm 210 is initiated to approach a side of a rack 110. The movement of the robot arm 210 is initiated to approach the rack apparatus 100. The robot arm 210 moves along a predefined approaching path AP toward a target region TR in the rack apparatus 100 the target location). This movement is coordinated to avoid collisions and ensure smooth operation.

The method M proceeds step S2, where an opening trigger signal is sent out when the robot arm 210 reaches a first determined position DP1 (indicated by a dashed line) in front of the rack apparatus 100 during the movement of the robot arm 210 to approach the side of the rack 110, for example, along an approaching path AP. As aforementioned, the controller 230 of the transfer robot 200 may send out the opening trigger signal to the door controller DC (optionally through the central control system 900) when the robot arm 210 reaches a first determined position DP1 (indicated by a dashed line) in front of the rack apparatus 100. The door controller DC may control the operations of the driving unit 129 based on the opening trigger signal. In some alternative embodiments, the motion sensor 127 may detect the presence of the robot arm 210, and send the opening trigger signal to the door controller DC or the driving unit 129 to activate. As a result of triggering of the opening trigger signal, the method M proceeds to step S3, where the doors 128A and 128B of the rack apparatus 100 is automatedly opened during the movement of the robot arm 210 to approach the side of the rack 110, for example, along the approaching path AP. For example, the automated door system 120 is actuated to move the door 128A to the second region P2 upon arrival of the robot arm 210 of the transfer robot 200 at the first determined position DP1 in front of the rack apparatus 100.

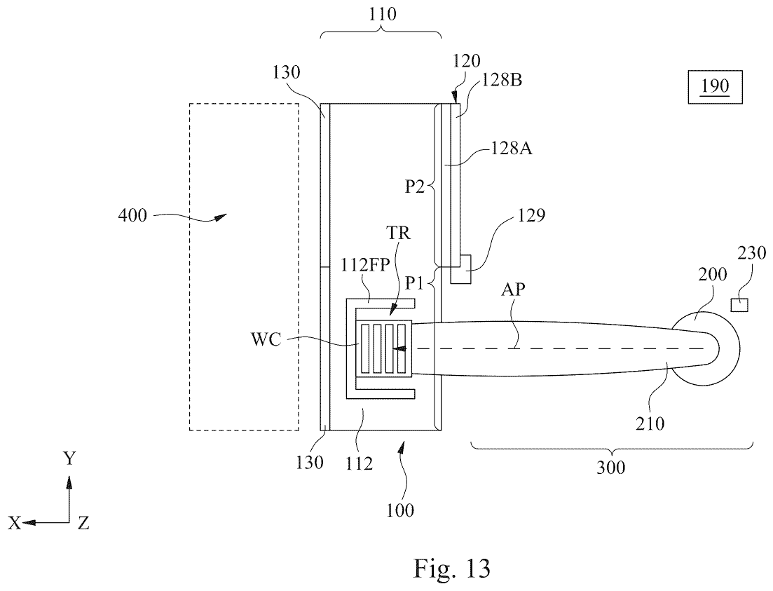

Reference is made to FIG. 10 and FIG. 13. The method M proceeds to step S4, where the robot arm 210 is caused to place the wafer carrier WC onto the rack apparatus 100. In present embodiments, the robot arm 210 extends into the rack apparatus 100, and place the wafer carrier WC onto a target region TR in the rack apparatus 100.

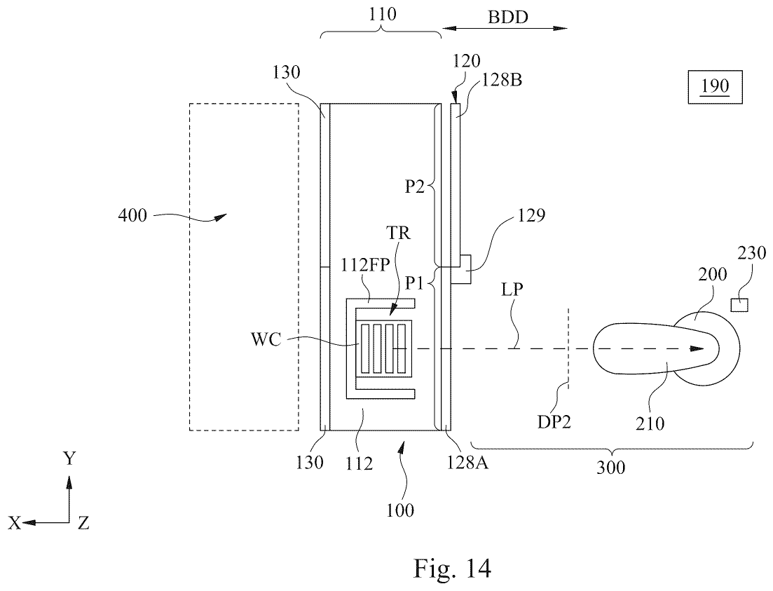

Reference is made to FIG. 10 and FIG. 14. The method M proceeds to step S5, where a movement of a robot arm 210 is initiated to move away from the rack 110. Stated differently, the robot arm 210 is instructed to retreat from the rack apparatus 100. The robot arm 210 moves along a predefined leaving path LP to leave the target region TR in the rack apparatus 100 the target location). This movement is coordinated to avoid collisions and ensure smooth operation.

The method M proceeds to step S6, where a closing trigger signal is sent out when the robot arm 210 reaches a second determined position DP2 (indicated by a dashed line) in front of the rack apparatus 100 during the movement of the robot arm 210 to move away from the rack 110, for example, along a leaving path LP. As aforementioned, the controller 230 of the transfer robot 200 may send out the closing trigger signal to the door controller DC (optionally through the central control system 900) when the robot arm 210 reaches the second determined position DP2 (indicated by a dashed line) in front of the rack apparatus 100. The door controller DC may control the operations of the driving unit 129 based on the closing trigger signal. In some alternative embodiments, the motion sensor 127 may send the opening trigger signal to the door controller DC or the driving unit 129 to activate. As a result of triggering of the closing trigger signal, the method M proceeds to step S7, where the doors 128A and 128B of the rack apparatus 100 are automatedly closed during the movement of the robot arm 210 along the leaving path LP. For example, the automated door system 120 is actuated to move/return the door 128A back to the first region P1. The second determined position DP2 may be the same as or different from the first determined position DP1 (referring to FIG. 12).

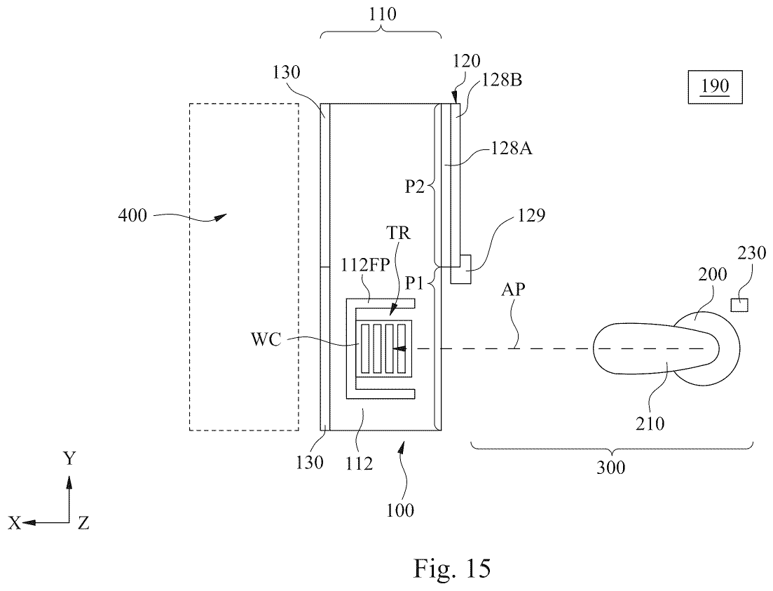

FIGS. 15-18 are top views of a rack apparatus 100 and a transfer robot 200 at various operating stages during transferring a wafer carrier WC away a rack apparatus according to some embodiments of the present disclosure. Reference is made to FIG. 10 and FIG. 15. The method M begins at step S1, where a movement of a robot arm 210 is initiated to approach a side of a rack 110. The movement of the robot arm 210 is initiated to approach the rack apparatus 100. The robot arm 210 moves along a predefined approaching path AP toward a target region TR in the rack apparatus 100 the target location). This movement is coordinated to avoid collisions and ensure smooth operation.

The method M proceeds step S2, where an opening trigger signal is sent out when the robot arm 210 reaches a first determined position DP1 (indicated by a dashed line) in front of the rack apparatus 100 during the movement of the robot arm 210 to approach the side of the rack 110, for example, along an approaching path AP. As aforementioned, the controller 230 of the transfer robot 200 may send out the opening trigger signal to the door controller DC (optionally through the central control system 900) when the robot arm 210 reaches the first determined position DP1 (indicated by a dashed line) in front of the rack apparatus 100. The door controller DC may control the operations of the driving unit 129 based on the opening trigger signal. In some alternative embodiments, the motion sensor 127 may detect the presence of the robot arm 210, and send the opening trigger signal to the door controller DC or the driving unit 129 to activate. As a result of triggering of the opening trigger signal, the method M proceeds to step S3, where the doors 128A and 128B of the rack apparatus 100 is automatedly opened during the movement of the robot arm 210 to approach the side of the rack 110, for example, along the approaching path AP. For example, the automated door system 120 is actuated to move the door 128A to the second region P2 upon arrival of the robot arm 210 of the transfer robot 200 at the first determined position DP1 in front of the rack apparatus 100. Alternatively, when the determination result indicates the robot arm 210 has not yet reached the first determined position DP1, the doors 128A and 128B of the rack apparatus 100 is remained closed.

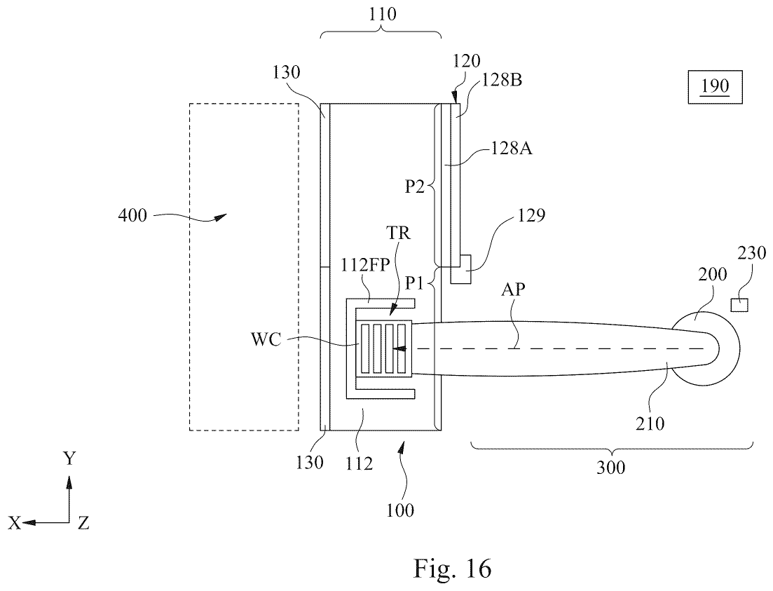

Reference is made to FIG. 10 and FIG. 16. The method M proceeds to step S4, where the robot arm 210 is caused to grip a wafer carrier WC from the rack apparatus 100. In present embodiments, the robot arm 210 extends into the rack apparatus 100, and grip the wafer carrier WC from the target region TR in the rack apparatus 100.

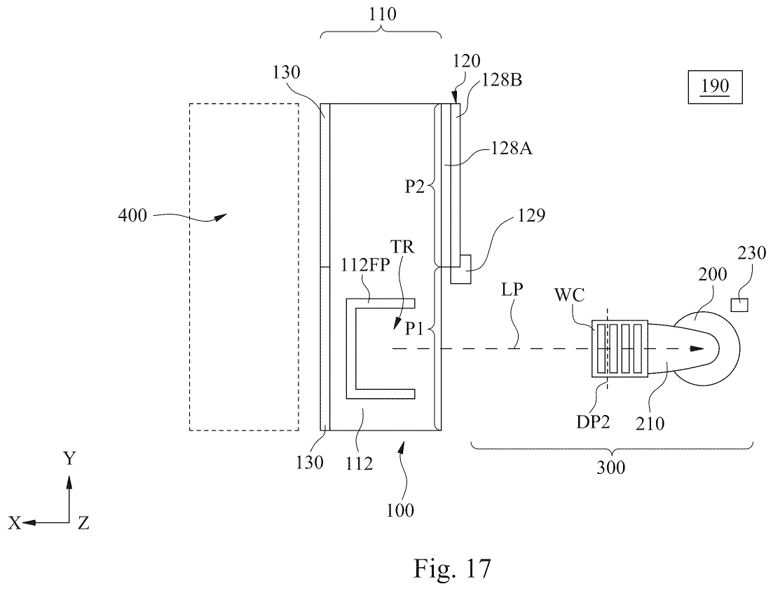

Reference is made to FIG. 10 and FIG. 17. The method M proceeds to step S5, where a movement of a robot arm 210 is initiated to move away from the rack 110. The robot arm 210 moves along a predefined leaving path LP to leave the target region TR in the rack apparatus 100 the target location). This movement is coordinated to avoid collisions and ensure smooth operation.

The method M proceeds to step S6, where a closing trigger signal is sent out when the robot arm 210 reaches a second determined position DP2 (indicated by a dashed line) in front of the rack apparatus 100 during the movement of the robot arm 210 along the leaving path LP. As aforementioned, the controller 230 of the transfer robot 200 may send out the closing trigger signal to the door controller DC (optionally through the central control system 900) when the robot arm 210 reaches the second determined position DP2 (indicated by a dashed line) in front of the rack apparatus 100. The door controller DC may control the operations of the driving unit 129 based on the closing trigger signal. In some alternative embodiments, the motion sensor 127 may send the opening trigger signal to the door controller DC or the driving unit 129 to activate.

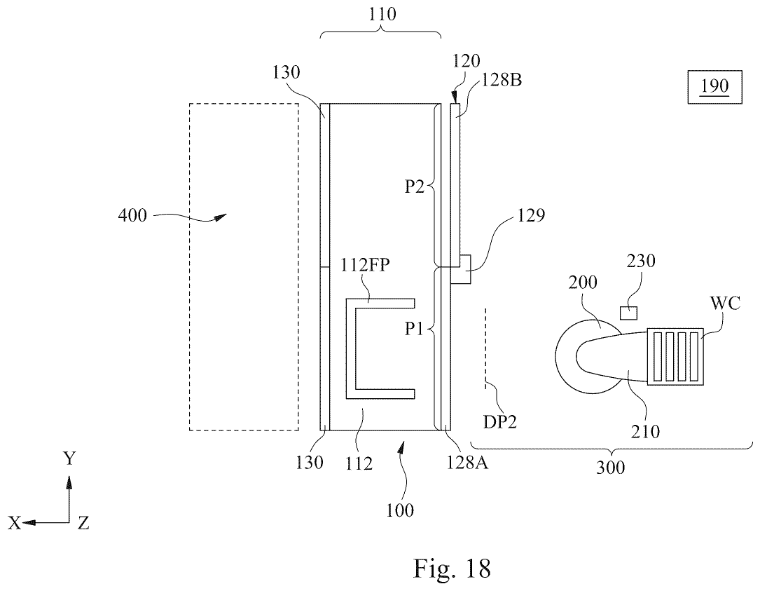

Reference is made to FIG. 10 and FIG. 18. As a result of triggering of the closing trigger signal, the method M proceeds to step S7, where the doors 128A and 128B of the rack apparatus 100 is automatedly closed during the movement of the robot arm 210 along the leaving path LP. For example, the automated door system 120 is actuated to move/return the door 128A back to the first region P1 upon arrival of the robot arm 210 of the transfer robot 200 at the second determined position DP2 in front of the rack apparatus 100. The second determined position DP2 may be the same as or different from the first determined position DP1 (referring to FIG. 14).

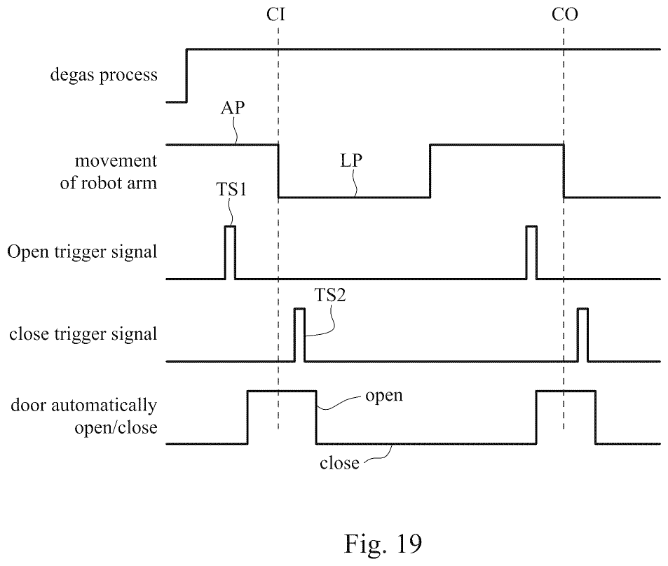

FIG. 19 shows pulses versus time for various steps when operating the rack apparatus according to some embodiments of the present disclosure. In FIG. 19, dashed lines CI and CO are used to indicate the timings of wafer carrier transfer. The dashed lines CI indicate the timing when the wafer carrier WC is moved onto the target region TR in the rack apparatus 100 the robot arm 210 (e.g., the step S5 and FIG. 13). And, the dashed lines CO indicate the timing when the wafer carrier WC is gripped away from the target region TR in the rack apparatus 100 by the robot arm 210 (e.g., the step S5 and FIG. 16).

As shown in FIGS. 12 and 15, when the robot arm 210 reaches a first determined position DP1 (indicated by a dashed line) in front of the rack apparatus 100 during the approaching path AP, the robot arm 210 may send out opening trigger signals TS1 to the door controller DC, and the doors 128A and 128B are automatedly opened according to the opening trigger signals TS1. And, as shown in FIGS. 14 and 17, when the robot arm 210 reaches a second determined position DP2 (indicated by a dashed line) in front of the rack apparatus 100 during the leaving path LP, the robot arm 210 may send out closing trigger signals TS2 to the door controller DC, the doors 128A and 128B are automatedly closed according to the closing trigger signals TS2. Alternatively, in some embodiments, the doors 128A and 128B are automatedly closed a period after the trigger signals TS1 is sent to the door controller DC (or the doors 128A and 128B are automatedly opened), and the trigger signals TS2 can be omitted.

Based on the above discussions, it can be seen that embodiments of the present disclosure offers advantages. It is understood, however, that other embodiments may offer additional advantages, and not all advantages are necessarily disclosed herein, and that no particular advantage is required for all embodiments. One advantage is that a fully automated de-gas rack is designed that meets the needs of automated scenarios without requiring manual operation, while also providing options for human intervention when necessary. Another advantage is that the fully automated de-gas rack is adapted for automated production, requiring no manual operation for loading and unloading.

According to some embodiments of the present disclosure, a method for operating a wafer carrier handling system is provided. The method includes initiating a movement of a robot arm of a transfer robot towards a rack apparatus along an approaching path, wherein the robot arm grips a wafer carrier; automatedly opening a door of the rack apparatus upon arrival of the robot arm of the transfer robot in front of the rack apparatus; after automatedly opening the door, placing the wafer carrier onto the rack apparatus using the robot arm; instructing the robot arm to retreat from the rack apparatus; and after the robot arm has been retreated from the rack apparatus, automatedly closing the door of the rack apparatus.

According to some embodiments of the present disclosure, a method for operating a wafer carrier handling system is provided. The method includes initiating a movement of a robot arm to approach a side of a rack, wherein an automated door system is located at a side of the rack; actuating the automated door system to move a door of the automated door system from a first region to a second region; gripping a wafer carrier from the rack using the robot arm; initiating a movement of the robot arm to move away from the rack, wherein the robot arm grips the wafer carrier; and actuating the automated door system to return the door of the automated door system from the second region back to the first region.

According to some embodiments of the present disclosure, a rack apparatus includes a rack and an automated door system. The rack includes a rack layer for receiving a wafer carrier. The automated door system is at a side of the rack, wherein the automated door system comprises a door, a rail assembly coupled with the door, and a driving unit. The rail assembly extends from a first region to a second region, and the driving unit is operable to move the door from the first region to the second region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for operating a wafer carrier handling system, comprising:
initiating a movement of a robot arm of a transfer robot towards a rack apparatus along an approaching path, wherein the robot arm grips a wafer carrier;
automatedly opening a door of the rack apparatus upon arrival of the robot arm of the transfer robot in front of the rack apparatus;
after automatedly opening the door, placing the wafer carrier onto the rack apparatus using the robot arm;
instructing the robot arm to retreat from the rack apparatus; and
after the robot arm has been retreated from the rack apparatus, automatedly closing the door of the rack apparatus.

2. The method of claim 1, wherein automatedly opening the door of the rack apparatus is triggered by a signal sent from the transfer robot.

3. The method of claim 1, wherein automatedly closing the door of the rack apparatus is triggered by a signal sent from the transfer robot.

4. The method of claim 1, wherein automatedly opening the door of the rack apparatus is performed during the movement of the robot arm of the transfer robot towards the rack apparatus along the approaching path.

5. The method of claim 1, wherein automatedly opening the door of the rack apparatus comprises:
moving the door from a first region to a second region, wherein the second region is aligned with the first region in a top view.

6. The method of claim 5, wherein automatedly closing the door of the rack apparatus comprises:
moving the door from the second region to the first region.

7. A method for operating a wafer carrier handling system, comprising:
initiating a movement of a robot arm to approach a side of a rack, wherein an automated door system is located at a side of the rack;
actuating the automated door system to move a door of the automated door system from a first region to a second region;
gripping a wafer carrier from the rack using the robot arm;
initiating a movement of the robot arm to move away from the rack, wherein the robot arm grips the wafer carrier; and
actuating the automated door system to return the door of the automated door system from the second region back to the first region.

8. The method of claim 7, wherein the second region is aligned with the first region in a top view.

9. The method of claim 7, further comprising:
using a light sensor of the automated door system, detecting a position of the door after moving the door from the first region to the second region.

10. The method of claim 7, further comprising:
using a light sensor of the automated door system, detecting a position of the door after returning the door from the second region back to the first region.

11. The method of claim 7, wherein gripping the wafer carrier from the rack comprises gripping the wafer carrier from a target region in the rack, wherein the target region is surrounded by a positioning element, and the positioning element has an opening facing the side of the rack.

12. The method of claim 7, further comprising:
exhausting a gas away from the rack.

13. The method of claim 7, wherein the automated door system comprises a rail assembly coupled with the door, wherein the rail assembly extends from the first region to the second region.

14. The method of claim 13, wherein the automated door system comprises a cover surrounding the rail assembly.

15. The method of claim 14, further comprising:
exhausting a gas away from the rail assembly through a hole of the cover.

16. A rack apparatus, comprising:
a rack comprising a rack layer for receiving a wafer carrier; and
an automated door system at a side of the rack, wherein the automated door system comprises a door, a rail assembly coupled with the door, and a driving unit, wherein the rail assembly extends from a first region to a second region, and the driving unit is operable to move the door from the first region to the second region.

17. The rack apparatus of claim 16, wherein the automated door system further comprises:
a first light sensor configured to detect the first region; and
a second light sensor configured to detect the second region.

18. The rack apparatus of claim 16, wherein the rack layer comprises a floor, the floor comprises a positioning element having an opening facing the side of the rack.

19. The rack apparatus of claim 16, further comprising:
a rail cover surrounding a rail of the rail assembly.

20. The rack apparatus of claim 19, further comprising:
a gas exhaust system gaseously connected with a hole of the rail cover.
